(19) United States
(12) Patent Application Publication
(10) Pub. No.: US 2005/0016465 A1
(43) Pub. Date: Jan. 27, 2005

(54) Electrostatic chuck having electrode with rounded edge

(75) Inventors: Kartik Ramaswamy, Santa Clara, CA (US); Jon M. McChesney, Santa Clara, CA (US); Ananda H. Kumar, Fremont, CA (US); Hamid Noorbakhsh, Fremont, CA (US)

Correspondence Address: APPLIED MATERIALS, INC.;Patent Department, M/S 2061, P.O. Box 450A, Santa Clara, CA, 95052, US

(73) Assignee: Applied Materials, Inc.

(21) Appl. No.: 10/626,156

(22) Filed: Jul. 23, 2003

(51) Int. Cl. C23C 16/00

(52) U.S. Cl. 118/728

(57) ABSTRACT

An electrostatic chuck provides reduced electric field effects about its peripheral edge. In one version, the chuck comprises a dielectric covering an electrode having a perimeter and a wire loop extending about the perimeter, the wire loop having a radially outwardly facing surface that is substantially rounded. Alternatively, the electrode may have a central planar portion comprising a top surface and a bottom surface, and a peripheral arcuate portion having a tip with a curvature length of at least about π/8 radians between a normal to the top surface of the central planar portion and a normal to the upper surface of the tip. The electrostatic chuck is used to hold a substrate in a process chamber of a substrate processing apparatus.

### BACKGROUND

Embodiments of the invention relate to an electrostatic chuck that may be used to hold a substrate in a substrate processing chamber.

In the fabrication of electronic circuits and displays, semiconductor, dielectric, or conductor materials are formed on a substrate, such as a silicon wafer or glass. The materials are typically formed by chemical vapor deposition (CVD), physical vapor deposition (PVD), oxidation and nitridation processes. Thereafter, the materials are etched to form features such as gates, vias, contact holes and interconnect lines. In a typical etching process, a patterned mask of photoresist or oxide hard mask is formed on the substrate by photolithography, the substrate is placed in a process chamber and a plasma is formed in the chamber to etch exposed portions of the substrate.

The process chamber has an electrostatic chuck 20 to hold the substrate in the chamber as illustrated in FIG. 1 (Prior Art). The electrostatic chuck 20 comprises a dielectric 24 covering an electrode 32 and having a receiving surface 28 on which to receive the substrate 4. The entire electrode 32 lies in the same horizontal plane. Typically, a DC electric potential is applied to the electrode 32 to apply an electrostatic force to the substrate 4 that clamps the substrate 4 to the receiving surface 28. A high voltage RF potential can also be applied to the electrode 32 to energize a process gas in the chamber to form a plasma to process the substrate 4.

However, one problem with such conventional chucks 20 arises when the high voltages or potentials applied to the electrode 32 of the chuck 20 leaks out as current leakage shown by the electric field vector 50 from the edges 48 of the electrode 32 through the sidewall edge 22 of the surrounding dielectric 24 and into the plasma. The current leakage 50 can weaken the clamping force applied on the substrate 4, causing the substrate 4 to be weakly held on the receiving surface 28 of the electrostatic chuck 20. Poor chucking force can cause the substrate 4 to shift position on the surface 28 or even be dislodged from the surface 28. An improperly positioned substrate 4 is exposed to a non-uniform plasma resulting in uneven processing across the surface of the substrate 4. In addition, the current leakage 50 can form an unstable plasma at the electrode edge 48 that can exacerbate the non-uniform processing of the substrate 4. The leakage problem is worsened when a chamber sidewall (not shown) opposing the dielectric sidewall edge 22 and facing the electrode edge 48, is grounded or maintained at a floating potential because the current from the electrode edge 48 has a short pathway through the dielectric sidewall edge 22 to reach the chamber sidewall.

Thus, it is desirable to have an electrostatic chuck that can securely hold a substrate. It is further desirable to have an electrostatic chuck with reduced current leakage from the electrode and through the sidewall edge of the chuck. It is also desirable to have an electrostatic chuck that is able to generate uniform electric fields across from the center to the edge of the electrode.

### SUMMARY

An electrostatic chuck to hold a substrate in a process chamber comprises an electrode having a perimeter. The electrode comprises a wire loop that extends substantially continuously about the perimeter, and the wire loop has a radially outwardly facing surface that is substantially rounded. Additionally, a dielectric covers the electrode.

In another version, the electrostatic chuck comprises an electrode having a central planar portion comprising a top surface and a bottom surface, and a peripheral arcuate portion having a tip with an upper surface. The peripheral arcuate portion has a curvature length of at least about π/8 radians between a normal to the top surface of the central planar portion and a normal to the upper surface of the tip. The peripheral arcuate portion can have a curvature diameter of at least about 3 micrometers. A dielectric covers the electrode.

A substrate processing apparatus for processing a substrate comprises a process chamber that includes the electrostatic chuck. The substrate processing apparatus also includes a gas distributor to introduce a process gas into the process chamber. A gas energizer energizes the process gas in the process chamber to process the substrate. A gas exhaust exhausts the process gas from the process chamber.

### DRAWINGS

These features, aspects, and advantages of the present invention will become better understood with regard to the following description, appended claims, and accompanying drawings which illustrate versions of the invention, where:

FIG. 1 (Prior Art) is a cross-sectional side view of an embodiment of a conventional electrostatic chuck having a planar electrode;

FIG. 2 is a cross-sectional side view of an embodiment of an electrostatic chuck having an electrode with a wire loop having a radially outwardly facing surface that is substantially rounded, and that extends substantially continuously about the perimeter of the electrode;

FIG. 3 is a cross-sectional side view of an embodiment of an electrostatic chuck having an electrode with a peripheral arcuate portion;

FIG. 4 is a schematic side view of an embodiment of a process chamber comprising the electrostatic chuck of FIG. 2.

### DESCRIPTION

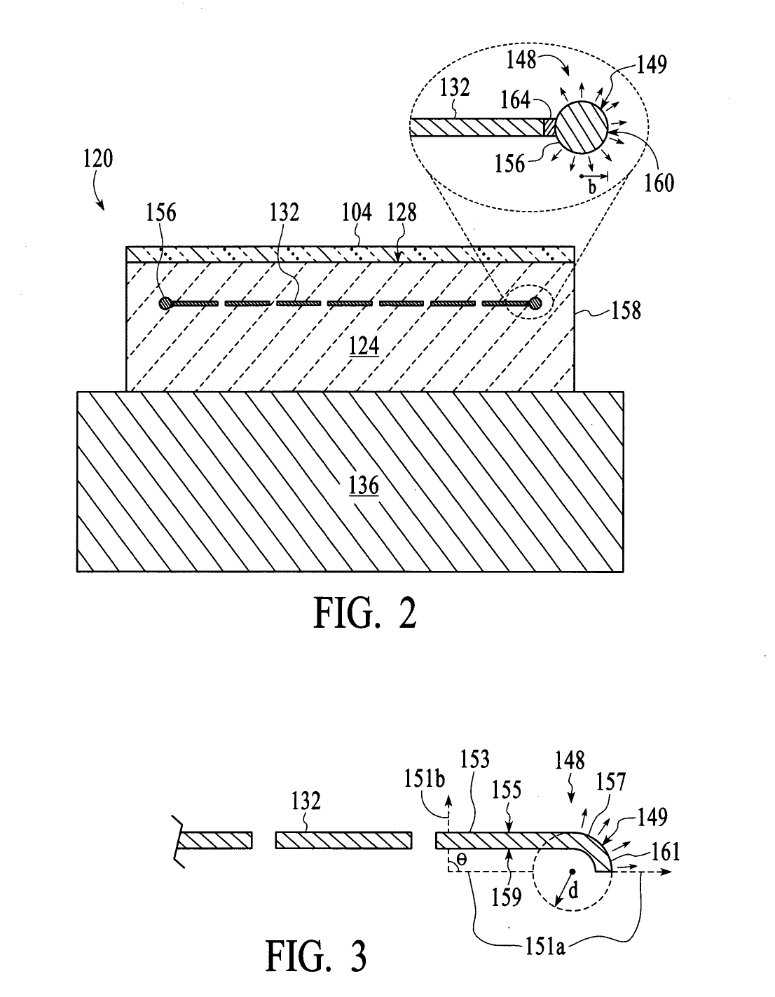

An electrostatic chuck 120 holds a substrate 104 in a process zone 112 during processing, as illustrated in the exemplary embodiment of FIG. 2. The electrostatic chuck 120 comprises a dielectric 124 with a receiving surface 128 on which to receive the substrate 104. The dielectric 124 typically comprises a ceramic, such as aluminum nitride or aluminum oxide. The dielectric ceramic can be doped with a dopant, such as titanium oxide in aluminum oxide, to make the material more semi-conductive to allow easier removal of accumulated surface charge. The electrostatic chuck 120 further comprises an electrode 132 that is covered by the dielectric 124. The dielectric 124 can cover the top surface of the electrode 132 in a continuous layer, or the electrode 132 may be embedded in the dielectric 124 so that the dielectric surrounds and encompasses the electrode.

The chuck electrode 132 typically is composed of a conductor, such as a metal, for example, copper, aluminum or molybdenum. Typically, the electrode 132 is shaped and sized to correspond to the shape and size of the substrate 104, for example, if the substrate 104 is a disk-shaped wafer, a disk-shaped electrode having a round or square cross-section can be used. The electrode 132 can be monopolar with a single segment that is maintained at one potential, or bipolar with two or more segments that are maintained at different potentials or polarities. In one version, the electrode 132 comprises a wire mesh—such as a grid of round wire, which is easier to embed into a dielectric 124. However, the electrode 132 can also be a metal plate hole stamped with apertures, or a continuous layer such as a sheet of metal.

The electrode 132 in the electrostatic chuck 120 has an edge 148 that is substantially rounded about a plane orthogonal to the plane of the receiving surface 128 of the electrostatic chuck 120, as for example illustrated in the embodiments shown in FIGS. 2 and 3, to reduce current leakage from the electrode 132. The edge 148 is a rounded portion of the electrode 132 that is generally orthogonal to the receiving surface 128 of the electrostatic chuck 120. The electrostatic chuck 120 has a lower electric field strength at the edge 148, where the electric field strength is the change in electric potential across a unit distance. The electric field vectors are shown as arrows in FIGS. 2 and 3, pointing in the direction of the electric field at points near the radially outwardly facing surface 149 of the edge 148 of the electrode 132, while the lengths of the vectors indicate the magnitude of the electric field at those points. The rounded edge 148 reduces the electric potential per unit area across the sidewall edge 158 of the chuck 120 such that electrical breakdown through the sidewall edge 158 of the dielectric 124 is less likely. The rounded edge 148 of the electrode 132 is located near the perimeter of the chuck 120 to reduce electric field emanations from the radially outermost or peripheral portion of the chuck 120.

In a first version, an exemplary embodiment of which is shown in FIG. 2, the electrode 132 comprises a wire loop 156 that extends substantially continuously about the perimeter 160 of the electrode 132. For example, while the substantially continuous wire loop 156 can have breaks, it should cover at least about 60% of the outer perimeter of the electrode 132 to reduce edge effects along most of the electrode perimeter. The rounded wire loop 156 reduces electric field emanations from any sharp edges or points along the perimeter of the electrode 132. The wire loop 156 has a radially outwardly facing surface 149, which is the surface distant from the center of the electrostatic chuck 120, that is substantially rounded. The substantially rounded wire loop has at least one radius of curvature of its outer edge. The rounded cross-section has a finite length with a sufficiently high curvature diameter (d) to reduce, or even substantially prevent, current leakage from the electrode 132 and through the sidewall edge 158 of the electrostatic chuck 120. For example, the wire loop 156 may have a cross-section that is substantially circular, and the cross-section of the wire loop can have a diameter that is larger than the cross-sectional thickness of the electrode. The wire loop 156 can be a circle, an ellipse, or a semi-ellipse. With the attached rounded wire loop 156, the electric field near the radially outwardly facing surface 149 of the edge 148 is weakened such that current leakage through the sidewall edge 158 is less likely to occur. The electric charge in the perimeter 160 distributes across the radially outwardly facing surface 149 such that the electric field at the radially outwardly facing surface 149 is weakened. The rounded wire loop 156 may be attached to the perimeter 160 of the electrode 132 with a conductive bond 164. For example, the wire loop 156 may be brazed onto the electrode 132 at the perimeter 160 using a brazing compound between the rounded wire loop 156 and the electrode 132. Alternatively, the electrode 132 my be stamped or pressed out of a metal sheet to have a radially outwardly facing surface 149 that is substantially rounded.

At an edge 148, a hypothetical circle can be drawn that defines the curvature at the edge 148, such as the curvature of the wire loop 156. The diameter of the circle is referred to as the curvature diameter (d). This hypothetical circle can hug the inside of a cross-section of the radially outwardly facing surface 149 along a substantially continuous and finite section of the circle's perimeter, as shown in FIG. 2. The degree of curvature at the radially outwardly facing surface 149 of the edge 148 is indicated by the diameter of this circle. For example, a sharper edge 148 has a greater curvature and thus corresponds to a smaller curvature diameter, while a smoother edge 148 has a lesser curvature and thus corresponds to a greater curvature diameter. An exemplary electrode 132 with desirable electrical performance has a perimeter with an edge 148 having a curvature diameter (d) of at least about 3 micrometers, or even at least about 4 micrometers for substantially improved performance. For example, the wire loop can have a diameter of at least about 3 micrometers. The electric field strength at the surface is approximately inversely proportional to the curvature diameter (d) at the edge 148.

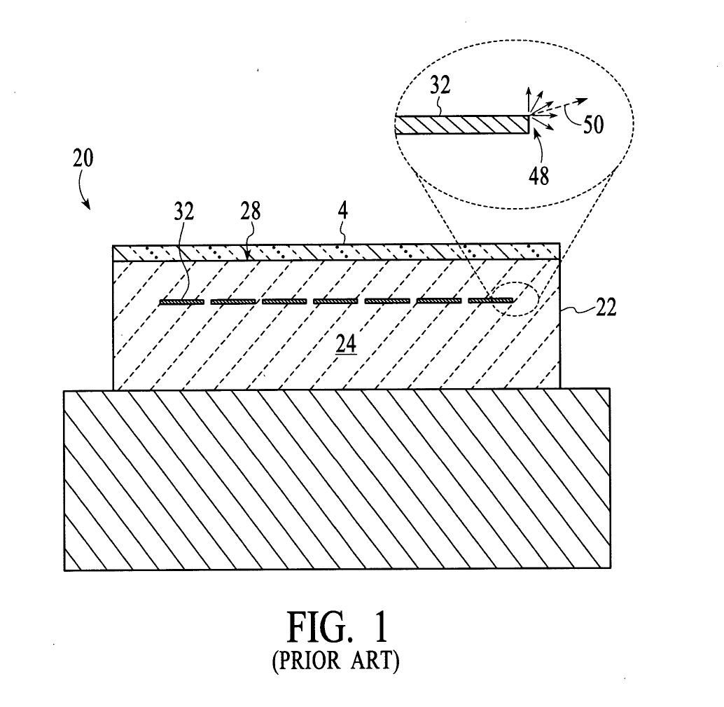

In contrast to the first version described above, a conventional electrode 32, as shown in FIG. 1 (Prior Art), has an edge that lies in a horizontal plane and consequently generates an undesirably strong electric field at its sharp edge 48. When an electric potential is applied to the conventional electrode 32, electric charge accumulates at the edge 48. Since the edge 48 is surrounded by electrically neutral space, electric charge gathers in the sharp edge 48 in a higher density than throughout the rest of the conventional electrode 32 to maintain a uniform potential throughout the conventional electrode 32. The high density of electric charge in the conventional electrode 32 causes a strong electric field to emanate from the edge 48, which can cause electrical breakdown in the adjacent dielectric material 24 and thereby also undesirable electrical discharge from the conventional electrode 32 through the sidewall 22 of the adjacent dielectric material 24. The electrical discharge can weaken the electrostatic holding strength of the electrostatic chuck 20 such that the substrate 4 is not securely held or is even unintentionally released. The electric field from the edge 48 is even stronger when chamber sidewalls directly facing the edge 48 are maintained at a floating or ground potential for example, to form a secondary electrode to generate or sustain a plasma in the chamber.

In a second version, an exemplary embodiment of which is illustrated in FIG. 3, the electrode 132 has a central planar portion 153 that makes up most of the area below the substrate receiving surface, and a peripheral arcuate portion 157 that is arcuate about a plane that is substantially orthogonal to the plane of the central portion 153. The central portion 153 comprises a top surface 155 and a bottom surface 159 that are each planar and substantially parallel to one another. The peripheral arcuate portion 157 of the electrode 132 is bowed in a substantially continuous a single or multi-radius arc which ends in a tip 161. For example, the arcuate portion 157 may be bowed through an angle (θ) that is sufficiently large to reduce, or even substantially prevent, current leakage from the edge 148 of the chuck 120. The angle (θ) refers to the angle formed between (i) a normal vector 151a to the upper radially outwardly facing surface 149 of the peripheral arcuate portion 157 and (ii) a normal vector 151b to the top surface 155 of the central planar portion 153. In one embodiment, the electrode edge 148 is bowed through an angle (θ) of at least about π/8 radians, substantially preventing current leakage by exposing the surrounding dielectric 124 to the smooth upper radially outwardly facing surface 149 of the peripheral arcuate portion 157.

As with the wire loop version, the peripheral arcuate portion 157 can also has a curvature diameter (d) of at least about 3 micrometers. The electrode 132 may be bowed in a downward or upward direction, and even in an inward direction. Preferably, the tip 161 of the peripheral arcuate portion 157 extends substantially entirely beyond the bottom surface 159 of the central planar portion 153, so that the electric field from the tip 161 is directed downward and not upward into the plasma. Bowing the electrode edge 148 exposes the side of the dielectric 124, which is particularly prone to electrical breakdown, to the rounded, bowed upper radially outwardly facing surface 149 rather than to a sharp tip of the electrode 132. When an electric potential is applied to the electrode 132, the electric field emerging from the peripheral arcuate portion 157 is weaker than the electric field would be from a sharp tip.

The electrostatic chuck 120 can also have a base 136 below the dielectric 124, which may be made from, for example, a metal or a ceramic. The process chamber 108 can also include a chuck lift (not shown) to raise and lower the electrostatic chuck 120, and thereby also the substrate 104, into and out of the process zone 112.

In one method of manufacturing the electrostatic chuck 120, a mold is filled to a first level with ceramic powder. An electrode 132 is adapted to have a rounded edge 148, as described above. For example, a wire loop 156 having an outer surface that is substantially rounded may be brazed or bonded to the perimeter 160 of the electrode 132, or the edge 148 of the electrode 132 may be bowed to have a peripheral arcuate portion 157. The wire loop 156 can be selected to have a radially outwardly facing portion with a sufficiently large curvature diameter (d) that is at least about 3 micrometers. For example, if the metal of the electrode 132 is sufficiently malleable, the electrode 132 can be shaped by selectively applying pressure at the edge 148 until an arcuate profile with a sufficiently large curvature diameter (d) to substantially prevent current leakage is obtained. Alternatively, the edge 148 of the electrode 132 may be rounded by mechanically abrading the edge 148 against a roughened surface. The electrode 132 is then placed on the ceramic powder at the first level. The mold is filled to a second level with more ceramic powder to cover the electrode 132. For a ceramic powder comprising aluminum oxide, the mixture in the mold can be sintered at a temperature of from about 500 to about 2000° C. to form a ceramic monolith enclosing the electrode 132.

The electrostatic chuck 120 described above is capable of holding a substrate 104 more securely. For example, an electrostatic chuck 120 having an electrode 132 according to the present invention can have a current leakage through the sidewall edge 158 of the dielectric 124 that is less than about 100 μA and more preferably less than 50 μA. Prior art chucks 20 often have a current leakage through the sidewall edge 22 of the dielectric 24 that is 300 μA or more. This three-fold reduction in the current leakage from the sidewall edge 158 allows the electrostatic chuck 120 to hold the substrate 104 reliably and with adequate force onto the receiving surface 128 during processing. The improved electrostatic chuck 120 can also prevent damage to the dielectric 124 surrounding the electrode 132 by reducing the likelihood of electrical discharges through the dielectric 124. It should be noted that the current leakage is dependent upon the voltage applied to the chuck 120, so the present current leakage values are for a voltage of −1500 to −2000 volts that is applied to the electrode 132 of the chuck 120. Also, the current leakage through the top surface 155 of the electrode 132 is also typically much smaller than the current leakage through the sidewall edge 158 of the chuck 120.

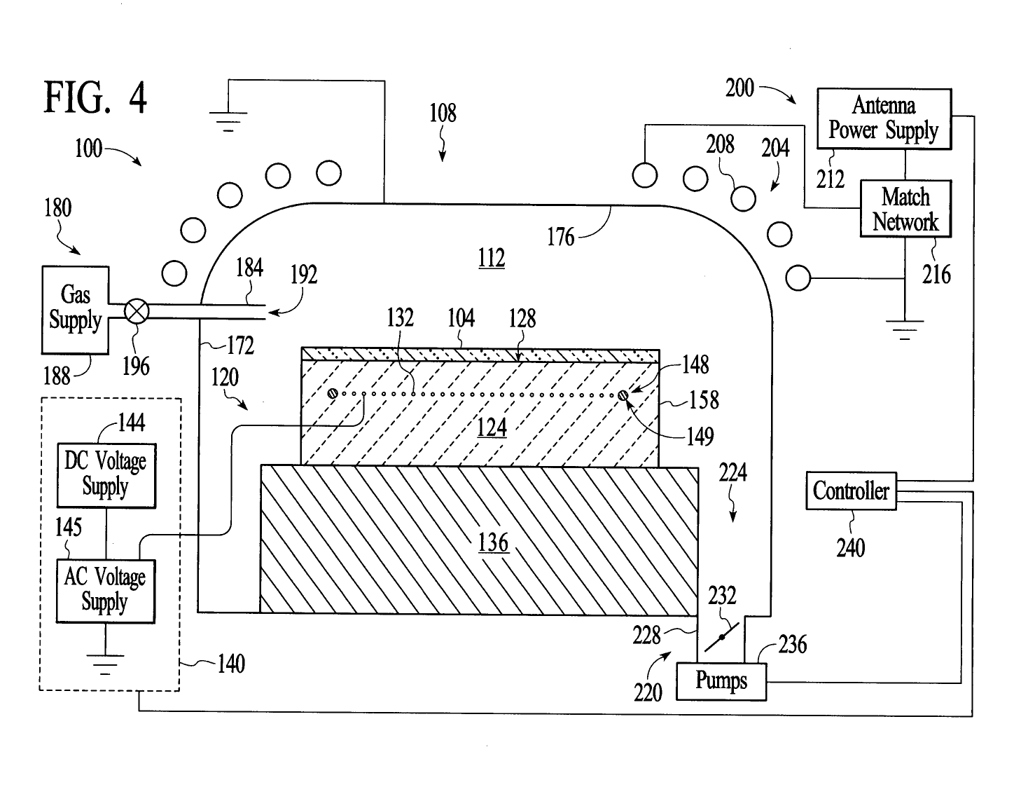

The electrostatic chuck 120 is used as part of a process chamber 108 in an apparatus 100 that is suitable for processing a substrate 104, as illustrated in FIG. 4. The process chamber 108 comprises walls 172, 176 that enclose the process zone 112 in which the substrate 104 is processed. For example, the process chamber 108 may comprise sidewalls 172, a bottom wall (not shown), and a ceiling 176 that faces the substrate 104. The ceiling 176 may act as an anode and may be grounded (as shown) or electrically biased by a power supply (not shown). The chamber 108 comprises walls 172, 176 fabricated from any of a variety of metal, ceramics, glasses, polymers, and composite materials. For example, metals commonly used to fabricate the chamber 108 include aluminum, anodized aluminum, “HAYNES 242,” “AI-6061,” “SS 304,” “SS 316,” and INCONEL. Anodized aluminum is typically preferred, and may have a surrounding liner (not shown). The ceiling 176 may comprise a flat, rectangular, arcuate, conical, dome or multiradius-arcuate shape.

The process chamber 108 may be an etch chamber, an embodiment of which is illustrated in FIG. 4, to etch material from a substrate 104, such as to etch a metal-containing material from the substrate 104. The particular embodiment of the apparatus 100 shown in FIG. 4 is suitable in the fabrication of electronic devices on a substrate 104, and is provided only to illustrate the invention. This particular embodiment should not be used to limit the scope of the invention. The substrate 104 to be etched may comprise a silicon, compound semiconductor or glass substrate, comprising dielectric, semiconductor or conductor material. The process chamber 108 may also be adapted to process other substrates 104, such as flat panel displays, polymer panels, or other electrical circuit receiving structures. The invention is especially useful for etching a metal-containing material on the substrate 104, the metal-containing material comprising, for example, a stack of different metal-containing layers (not shown). A typical process sequence for forming the etched features comprises the steps of (1) sequentially depositing the layers on the substrate 104, (2) forming an overlying mask layer that captures a pattern that is to be transferred into the metal-containing material, and is typically composed of photoresist, but can be made of other materials, such as silicon dioxide or silicon nitride, and (3) etching the substrate 104 to transfer the pattern captured in the mask into the metal-containing material, for example to form the etched features.

The electrostatic chuck 120 electrostatically holds the substrate 104 in the process chamber 108 and regulates the temperature of the substrate 104. The electrostatic chuck 120 is connected to an electrode voltage supply 140 comprising an AC voltage supply 145 that applies an alternating voltage to the electrode 132 to sustain the plasma by affecting the ion energy of the plasma. A DC voltage supply 144 also biases the electrode 132 to create an electrostatic downward force on the substrate 104. In one embodiment, the electrode voltage supply 140 applies an electric potential to the electrode 132 of from about −700 to about −3000 volts with respect to the plasma, or even from about −1500 to −2000 volts.

The substrate processing apparatus 100 further comprises a gas distributor 180 that introduces a process gas into the process chamber 108 to process the substrate 104. The gas distributor 180 comprises a gas feed conduit 184 that can transport the process gas from a gas supply 188 to one or more gas outlets 192 in the process chamber 108. A gas flow valve 196 regulates the flow of the process gas through the gas feed conduit 184, and therefore through the gas outlets 192. From the gas outlets 192, the process gas is released into the process zone 112. For example, a gas outlet 192 may be located peripherally around the substrate 104 (as shown in FIG. 4).

In one version, the substrate 104 is etched in a process gas comprising an etchant gas that reacts with the substrate 104, for example that reacts with a metal-containing material on the substrate 104, to form volatile gaseous compounds. The etchant gas comprises a composition containing halogen-containing gases that when energized react with and etch the metal-containing material. For etching aluminum or aluminum alloys and compounds, suitable halogen-containing etchant gases may comprise one or more chlorine-containing gases, such as for example, HCl, BCl₃, Cl₂, and mixtures thereof. For etching tungsten or tungsten alloys and compounds, fluorine-containing gases, such as SF₆, NF₃ or F₂, and mixtures thereof, may be used. Alloys or compounds that contain copper or titanium can be etched with fluorine or chlorine-containing gases. Although the invention is illustrated by particular compositions of halogen gases, it should be understood that the present invention should not be limited to the halogen gases described herein.

A gas energizer 200 energizes the process gas introduced into the chamber 108 to form a plasma to process the substrate 104. The gas energizer 200 couples electromagnetic power, such as RF (radio frequency) power, into the process gas. A suitable gas energizer 200 comprises an inductor antenna 204 having one or more inductor coils 208 above the ceiling 176 of the chamber 108. The ceiling 176 may comprise a dielectric material that is permeable to the electromagnetic energy, such as silicon or silicon dioxide. An antenna power supply 212 applies AC power, such as RF power, to the antenna via a match network 216 that tunes the applied power to optimize the inductive coupling of the power to the process gas.

The process gas in the chamber 108 is exhausted by a gas exhaust 220 that includes an exhaust conduit 224, an exhaust line 228, a throttle valve 232, and pumps 236 that can include roughing and turbo-molecular pumps. The pumps 236 may further comprise scrubber systems to clean the exhaust gas. The exhaust conduit 224 is a port or channel that receives the exhaust gas provided in the chamber 108, and that is typically positioned around the periphery of the substrate 104. The exhaust line 228 connects the exhaust conduit 224 to the pumps 236, and the throttle valve 232 in the exhaust line 228 may be used to control the pressure of the process gas in the chamber 108.

The substrate processing in the chamber 108 may be implemented using a controller 240. The controller 240 comprises a central processing unit (CPU) interconnected with a memory and peripheral control components. The CPU may comprise, for example, a 68040 microprocessor, fabricated by Synergy Microsystems Inc., San Diego, Calif. The controller 240 comprises a computer program product, which comprises program code embodied on a computer-readable medium, such as the memory of the controller 240. The program code can be written in any conventional computer-readable programming language, such as for example, assembly language or C++. Suitable program code is entered into a single file, or multiple files, using a conventional text editor, and stored or embodied in the computer-readable medium. If the entered code text is in a high level language, the code is compiled, and the resultant compiler code is then linked with an object code of precompiled library routines. To execute the linked compiled object code, the operator invokes the program code, causing the controller 240 to load the object code into the computer-readable medium. The CPU reads and executes the program code to perform the tasks identified therein.

Although exemplary embodiments of the present invention are shown and described, those of ordinary skill in the art may devise other embodiments that incorporate the present invention, and which are also within the scope of the present invention. For example, the electrostatic chuck 120 described herein can be used in a deposition chamber or another chamber. Also, the electrostatic chuck 120 may comprise materials other than those specifically mentioned, as would be apparent to one of ordinary skill in the art. Furthermore, the terms below, above, bottom, top, up, down, first, and second, and other relative or positional terms are shown with respect to the exemplary embodiments in the Figures and are interchangeable insofar as objects can be rotated or translated in space. Therefore, the appended claims should not be limited to the descriptions of the preferred versions, materials, or spatial arrangements described herein to illustrate the invention.

1. An electrostatic chuck to hold a substrate in a process chamber, the electrostatic chuck comprising:
(a) an electrode comprising a wire loop that extends substantially continuously about a perimeter of the electrode and has a radially outwardly facing surface that is substantially rounded; and
(b) a dielectric covering the electrode.

2. An electrostatic chuck according to claim 1 wherein the wire loop has a substantially circular cross-section.

3. An electrostatic chuck according to claim 2 wherein the substantially circular cross-section has a diameter that is larger than the cross-sectional thickness of the electrode.

4. An electrostatic chuck according to claim 1 wherein the electrode comprises a wire mesh.

5. An electrostatic chuck according to claim 1 wherein the wire loop has a diameter of at least about 3 micrometers.

6. An electrostatic chuck according to claim 1 further comprising a sidewall edge and wherein the current leakage through the sidewall edge is less than about 100 μA.

7. A substrate processing apparatus for processing a substrate, the substrate processing apparatus comprising:
(1) a process chamber comprising the electrostatic chuck of claim 1 to hold a substrate in the process chamber;
(2) a gas distributor to introduce a process gas into the process chamber;
(3) a gas energizer to energize the process gas in the process chamber to process the substrate; and
(4) a gas exhaust to exhaust the process gas from the process chamber.

8. An electrostatic chuck to hold a substrate in a process chamber, the electrostatic chuck comprising:
(a) an electrode comprising:
(i) a central planar portion comprising a top surface and a bottom surface, and
(ii) a peripheral arcuate portion having a tip with an upper surface, the arcuate portion having curvature length of at least about π/8 radians between a normal to the top surface of the central planar portion and a normal to the upper surface of the tip; and
(b) a dielectric covering the electrode.

9. An electrostatic chuck according to claim 8 wherein the peripheral arcuate portion has a curvature diameter of at least about 3 micrometers.

10. An electrostatic chuck according to claim 8 wherein the peripheral arcuate portion the tip of the peripheral arcuate portion extends substantially entirely beyond the bottom surface of the central planar portion.

11. An electrostatic chuck according to claim 8 wherein the electrode comprises a wire mesh.

12. An electrostatic chuck according to claim 8 further comprising a sidewall edge and wherein the current leakage through the sidewall edge is less than about 100 μA.

13. A substrate processing apparatus for processing a substrate, the substrate processing apparatus comprising:
(1) a process chamber comprising an electrostatic chuck according to claim 8 to hold a substrate in the process chamber;
(2) a gas distributor to introduce a process gas into the process chamber;
(3) a gas energizer to energize the process gas in the process chamber to process the substrate; and
(4) a gas exhaust to exhaust the process gas from the process chamber.

14. An electrostatic chuck to hold a substrate in a process chamber, the electrostatic chuck comprising:
(a) an electrode comprising:
(1) a central planar portion comprising a top surface and a bottom surface; and
(2) a peripheral arcuate portion having a tip, the arcuate portion having:
(i) a curvature length of at least about π/8 radians between a normal to the top surface of the central planar portion and a normal to the upper surface of the tip; and
(ii) a curvature diameter of at least about 3 micrometers; and
(b) a dielectric covering the electrode.

15. An electrostatic chuck according to claim 14 further comprising a sidewall edge and wherein the current leakage through the sidewall edge is less than about 100 μA.

16. An electrostatic chuck according to claim 14 wherein the electrode comprises a wire mesh.

17. A substrate processing apparatus for processing a substrate, the substrate processing apparatus comprising:
(a) a process chamber comprising an electrostatic chuck according to claim 14 to hold a substrate in the process chamber;
(b) a gas distributor to introduce a process gas into the process chamber;
(c) a gas energizer to energize the process gas in the process chamber to process the substrate; and
(d) a gas exhaust to exhaust the process gas from the process chamber.
